(19) United States
(12) Patent Application Publication
(10) Pub. No.: US 2026/0075929 A1
(43) Pub. Date: Mar. 12, 2026

(54) JFET WITH INTEGRATED TEMPERATURE SENSOR

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US)

(73) Assignee: Microchip Technology Incorporated, Chandler, AZ (US)

(21) Appl. No.: 19/240,465

(22) Filed: Jun. 17, 2025

Related U.S. Application Data
(60) Provisional application No. 63/691,730, filed on Sep. 6, 2024.

(51) Int. Cl. H10D 84/80; H01L 23/34; H10D 1/00; H10D 1/47; H10D 30/01; H10D 30/83; H10D 62/832; H10D 62/834; H10D 84/01

(52) U.S. Cl. CPC H10D 84/817; H10D 1/47; H10D 30/831; H10D 62/834; H10W 40/00; H10D 1/021; H10D 30/0515; H10D 62/8325; H10D 84/01

(57) ABSTRACT

A junction field-effect transistor device includes an integrated temperature sensor, and a method of making the same is disclosed. A temperature sensor material having a first charge carrier polarity is implanted into an area of semiconductor material having a second charge carrier polarity, with the area being located adjacent to the junction field-effect transistor. The sensor material contains dopants and exhibits an electrical resistance that increases with a number of ionized ones of the dopants. The number of ionized dopants increases with the temperature of the material. First and second electrical terminals are provided spaced-apart on the sensor material for measuring the electrical resistance of the material. The measured electrical resistance may be translated into a temperature value for the junction field-effect transistor.

### RELATED APPLICATION

The present U.S. non-provisional patent application is related to and claims priority benefit of an earlier-filed U.S. provisional patent application titled “JFET with Integrated Temperature Sensor,” Ser. No. 63/691,730, filed Sep. 6, 2024. The entire content of the identified earlier-filed application is incorporated by reference as if fully set forth herein.

### FIELD

The present disclosure relates to junction field effect transistors and methods of making them, and more particularly, the various examples described herein concern a junction field-effect transistor device with an integrated temperature sensor, and a method of making a junction field-effect transistor device with an integrated temperature sensor.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide a JFET device with an integrated temperature sensor, and a method of making a JFET device with an integrated temperature sensor. More specifically, an electrical resistor may be implanted or otherwise provided adjacent to the JFET, wherein the electrical resistance increases with a number of ionized dopants in the resistor material, and the number of ionized dopants increases with temperature, so that the measured electrical resistance of the resistor can be translated into a temperature value for the JFET. Examples advantageously provide a compact and low-cost solution allowing for real-time temperature monitoring with high accuracy and without requiring additional masks or processing steps.

In an example, a JFET device may have an integrated temperature sensor. The JFET device may include a junction field-effect transistor and a temperature sensor material. The temperature sensor material may have a first charge carrier polarity and may be implanted into an area of semiconductor material having a second charge carrier polarity. The area of semiconductor material may be adjacent to the junction field-effect transistor. The temperature sensor material may contain a plurality of dopants and may exhibit an electrical resistance that increases with a number of ionized ones of the dopants, with the number of ionized dopants increasing with a temperature of the temperature sensor material. First and second electrical terminals may be provided spaced-apart on the temperature sensor material to measure the electrical resistance of the temperature sensor material, wherein the electrical resistance measured between the first and second electrical terminals may be translated into a temperature value for the integrated temperature sensor and the junction field-effect transistor.

In another example, a JFET device having an integrated temperature sensor may be provided. The device may include a junction field-effect transistor having a gate. The device may also include a temperature sensor material having a first charge carrier polarity. The temperature sensor material may be implanted into an area of semiconductor material having a second charge carrier polarity, wherein the area is adjacent to the gate of the junction field-effect transistor. The temperature sensor material may have a thickness between one-tenth (0.1) micrometer and one-half (0.5) micrometer. The temperature sensor material may contain a plurality of dopants and may exhibit an electrical resistance that increases with a number of ionized ones of the dopants, with the number of ionized dopants increasing with a temperature of the temperature sensor material. First and second electrical terminals may be provided spaced-apart on the temperature sensor material to measure the electrical resistance of the temperature sensor material, wherein the electrical resistance measured between the first and second terminals may be translated into a temperature value for the integrated temperature sensor and the junction field-effect transistor, and wherein the integrated temperature sensor is capable of measuring a range of electrical resistance corresponding to a range of temperatures between a room temperature and a temperature at which all the dopants are ionized.

In yet another example, a method of making a JFET device with an integrated temperature sensor may include the following operations. An area of semiconductor material having a first charge carrier polarity may be provided adjacent to a gate of a junction field-effect transistor. A temperature sensor material having a second charge carrier polarity may be provided in the area of semiconductor material. The temperature sensor material may contain a plurality of dopants and may exhibit an electrical resistance that increases with a number of ionized ones of the dopants, with the number of ionized dopants increasing with a temperature of the temperature sensor material. First and second electrical terminals may be provided spaced-apart on the temperature sensor material to measure the electrical resistance of the temperature sensor material. The electrical resistance measured between the first and second terminals may be translated into a temperature value for the integrated temperature sensor and the junction field-effect transistor, and the integrated temperature sensor may be capable of measuring a range of temperatures between a room temperature and a temperature at which all the dopants are ionized.

Each of the preceding examples may further include any one or more of the following features, if such features are not already included in such examples. The thickness of the temperature sensor material may be approximately between one-tenth (0.1) micrometer and one-half (0.5) micrometer. The junction field-effect transistor may include a gate, and one of the first and second electrical terminals may be connected to the gate. The integrated temperature sensor may be capable of measuring a range of temperatures between a room temperature and a temperature at which all the dopants are ionized. The temperature at which all the dopants are ionized may be approximately two thousand (2000) degrees Celsius. The number of the dopants may determine the electrical resistance of the temperature sensor material, and more dopants results in lower electrical resistance. The dopants may be substantially any suitable dopants, such as boron, aluminum, gallium, or indium. The temperature sensor material may be P-type, and the semiconductor material may be N-type.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of a JFET device with an integrated temperature sensor;

FIG. 2 is a flowchart of operations in an example of a method of making a JFET device with an integrated temperature sensor;

FIG. 3A is a cross-sectional elevation view of the result of an operation in the method of FIG. 2, wherein an area of N-type epitaxial material is provided;

FIG. 3B is a cross-sectional elevation view of the result of an operation in the method of FIG. 2, wherein a source material, a gate material, and a temperature sensor material are implanted in the N-type epitaxial material; and

FIG. 3C is a cross-sectional elevation view of the result of an operation in the method of FIG. 2, wherein electrical terminals are provided, including spaced-apart electrical terminals on the temperature sensor material.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

For some applications, it may be desirable to monitor the temperature of an operating JFET. Broadly, examples provide a JFET with an integrated temperature sensor, and a method of making a JFET with an integrated temperature sensor. More specifically, an electrical resistor including P+ material may be implanted or otherwise provided adjacent to the JFET, wherein the electrical resistance increases with a number of ionized P+ dopants in the P+ material, and the number of ionized dopants increases with temperature, so that the measured electrical resistance of the resistor can be translated into a temperature value for the JFET. Examples advantageously provide a compact and low-cost solution allowing for real-time temperature monitoring with high accuracy and without requiring additional masks or processing steps.

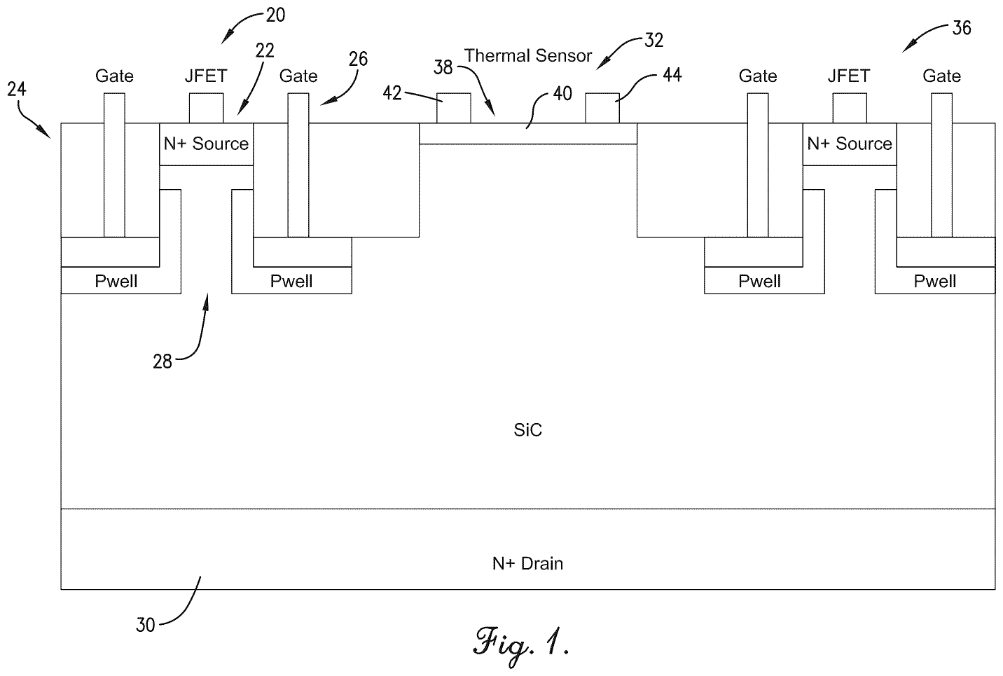

Referring to FIG. 1, a JFET device with an integrated temperature sensor may include a first JFET 20, including a source 22, first and second gates 24, 26, a channel 28, a drain 30, and the integrated temperature sensor 32. As shown in FIG. 1, the integrated temperature sensor 32 may be located in a space between the first JFET 20 and a second JFET 36, in which case the temperature value derived from the resistor may apply to both JFETs 20, 36. The second JFET 36 may be constructed different from or substantially similar or identical to the first JFET 20.

The integrated temperature, or thermal, sensor 32 may include an electrical resistor 38 including material 40 implanted or otherwise provided adjacent to the first JFET 20 or between the spaced-apart first and second JFETs 20, 36. The integrated temperature sensor 32 may include spaced-apart first and second electrical terminals 42, 44. The material 40 may have an opposite charge carrier polarity than the charge carrier polarity of the area of the volume of semiconductor material in which the material is located. In the illustrated example, the drift region of the volume of semiconductor material is N-type (meaning the semiconductor material is formed (e.g., epitaxially grown) of a doped N-type material, such as silicon or silicon carbide, and then provided with various structures of the JFET (including the source (which may be a higher doped N-type material) and the gates (which are opposite polarity P-type material)), and the material 40 is P-type. More particularly, the area of the volume of semiconductor material in which the P-type material 40 is located may be adjacent at least one of the JFETs 20, 36. In the illustrated example, the P-type material 40 may extend continuously between the JFETs 20, 36, although certain aspects contemplate the material 40 not contacting one or both of the JFETs. The material 40 may be the same P-type material used in the gates 24, 26, which in the illustrated example is P+ material. The P+ material 40 may contain P+ dopants such as boron, aluminum, gallium, or indium. The amount of P+ dopants determine the sheet resistance of the P+ resistor 38, wherein more dopants (i.e., a higher P+ implant dose) results in less sheet resistance (i.e., the resistor 38 is more electrically conductive). The electrical resistance increases with a number of ionized P+ dopants in the temperature sensor material 40, and the number of ionized dopants increases with temperature. Thus, electrical resistance can be measured between the first and second terminals 42, 44 and translated into a temperature value for the JFET 20 or JFETs 20, 36.

The thickness of the resistor 38 may be determined by the P+ implant dose/energy which was used to make the gates 24, 26, and may be approximately between one-tenth (0.1) micrometer (um) and one-half (0.5) um. One of the sensor terminals 42, 44 may be connected to a gate of the adjacent JFET. Broadly, the temperature sensor 32 may be capable of measuring temperatures from approximately between room temperature and the temperature at which all of the dopants are activated (approximately two-thousand (2000) degrees Celsius (C.)).

In operation, an input voltage, Vds, may be applied across the source 22 and the drain 30 to cause electron drift/movement through the channel 28 from the source 22 to the drain 24, and a control voltage, Vgs, may be applied across the source 22 and the gates 24, 26 to control the width of the depletion region at the PN junctions where the charge carriers of the P- and N-type materials diffuse into each other, which “depletes” the available concentrations of majority charge carrier in each material, and thereby control the current, Id, from the drain 24 to source 22. Thus, the source 22, the first gate 24, and the second gate 26 may cooperate under Vgs to control the current, Id, through the channel 28. If Vgs=0 V and Vds>0 V, electrons drift, or move, from the source 22 to the drain 30, resulting in the current, Id, from the drain 30 to the source 22, and increased depletion regions at the PN junctions. If Vds=pinch-off voltage (Vp), then the depletion regions increase in size and grow sufficiently close to each other across the channel 28 that the current, Id, through the channel 28 cannot increase, so Id=maximum drain current (Idss). In the present examples, an increase in temperature results in an increase in electrical resistance of the P+ material 40 of the electrical resistor 38 of the temperature, or thermal, sensor 32, so the electrical resistance of the sensor 32 can be measured and translated into a temperature value for the JFET 20 or JFETs 20, 36.

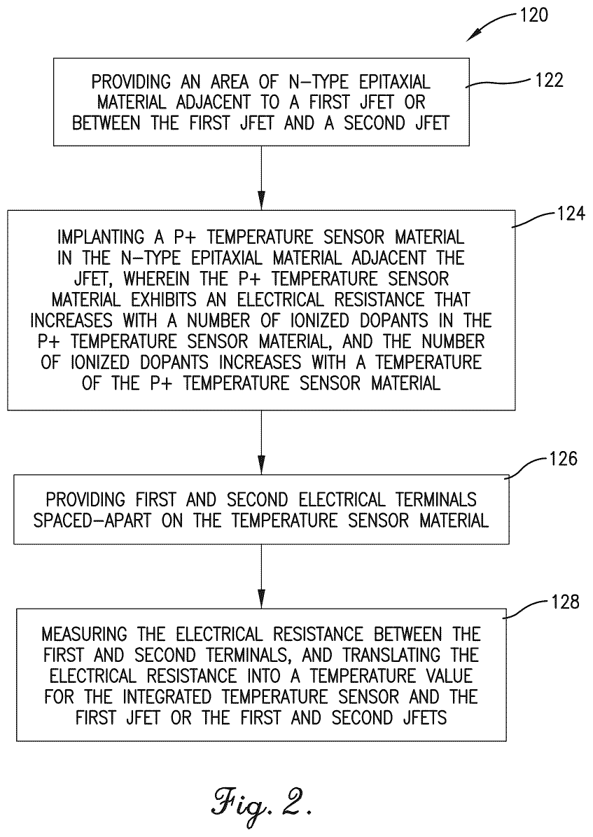

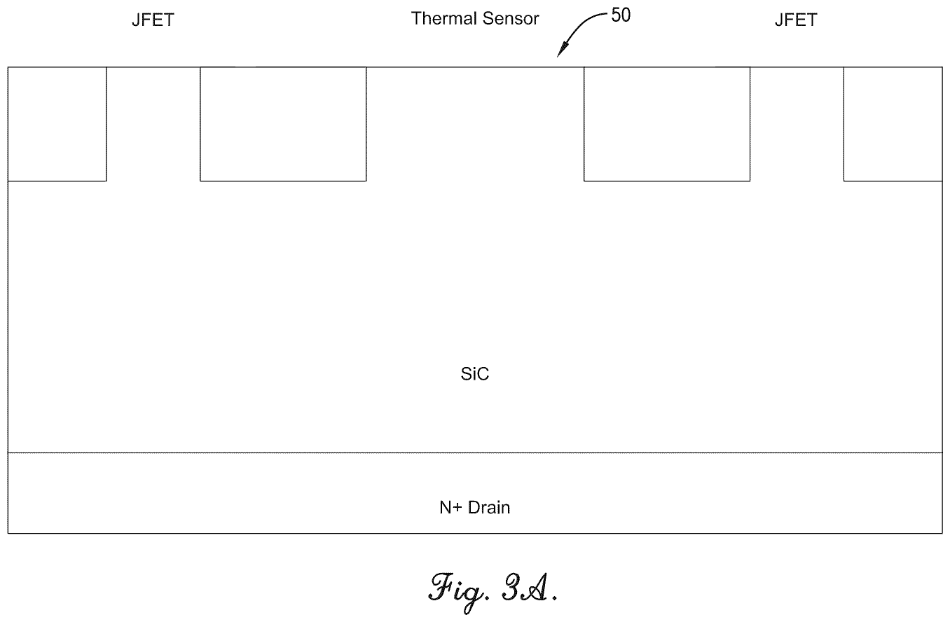

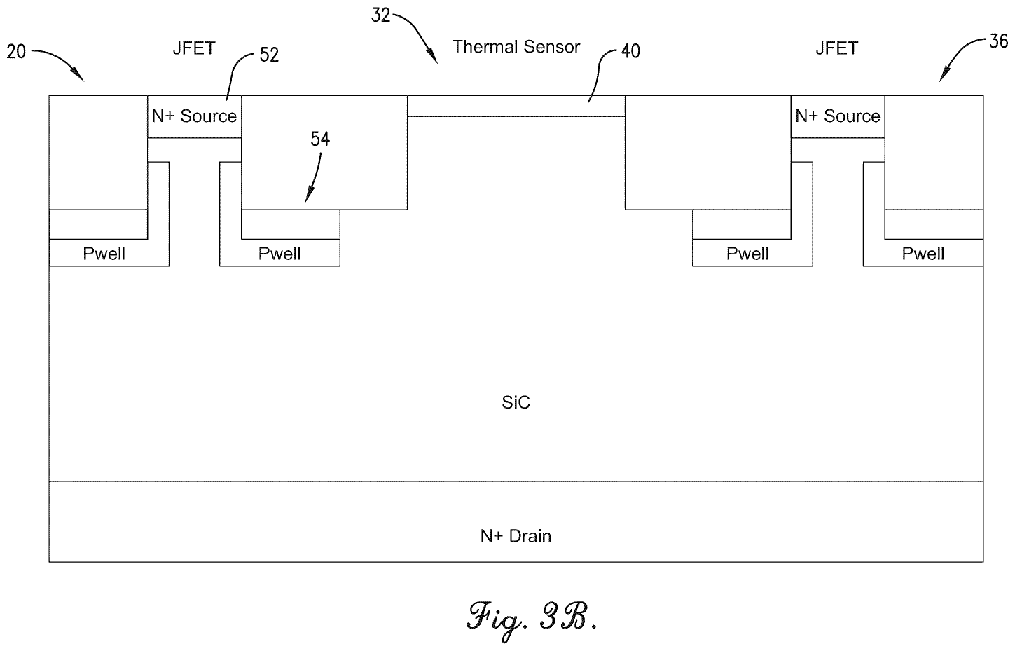

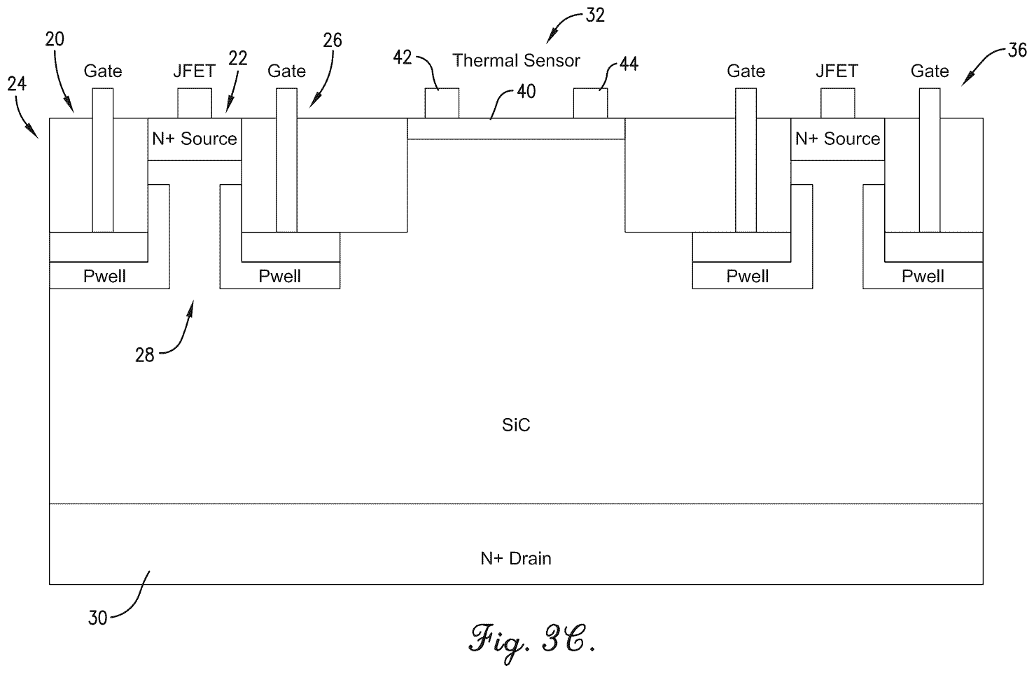

Referring to FIG. 2, an example of a method 120 of manufacturing the JFET 20 with an integrated temperature sensor of FIG. 1 may include the operations set forth below. Referring additionally to FIGS. 3A-C, example results are shown of the operations of the method 120 and intermediate stages of production of the JFET 20.

A foundation of N-type epitaxial material 50 (e.g., SiC doped with nitrogen) may be provided, and an area of the N-type epitaxial material 50 may be provided adjacent to a location of a first JFET 20, or between the first JFET 20 and a second JFET 36, as shown in 122 and seen in FIG. 3A and FIG. 1. N+ source material 52, P+ gate material 54, and P+ temperature sensor material 40 may be implanted (using, e.g., an ion implanter) in the N-type epitaxial material 50 in a process of making both the JFETs 20, 36 and the integrated temperature sensor 32, as shown in 124 and seen in FIG. 3B. The P+ temperature sensor material 40 may contain a plurality of P+ dopants, and has an electrical resistance and can be treated as an electrical resistor 38. The P+ dopants may be substantially any suitable dopants, such as boron, aluminum, gallium, or indium.

Electrical terminals may be formed or otherwise provided on the source material 52 and the gate material 54, and first and second electrical terminals 42, 44 may be formed or otherwise provided spaced-apart on the temperature sensor material 40 to form the temperature sensor 32, as shown in 126 and seen in FIG. 3C. In particular, the first and second electrical terminals 42, 44 may be provided on the temperature sensor material 40 so that the electrical resistance through the temperature sensor material 40 can be measured, wherein the electrical resistance increases with a number of ionized P+ dopants in the temperature sensor material 40, and the number of ionized dopants increases with temperature. The electrical resistance may be measured between the first and second terminals 42, 44 and translated into a temperature value for the JFET 20, as shown in 128.

The thickness of the resistor 38 may be determined by the P+ implant dose/energy which was used to make the gates 24, 26, and may be approximately between one-tenth (0.1) micrometer (um) and one-half (0.5) um. One of the sensor electrical terminals 42, 44 may be connected to a gate of the JFET. Broadly, the temperature sensor 32 may be capable of measuring temperatures from approximately between room temperature and the temperature at which all of the P+ dopants are activated, which may be approximately two-thousand (2000) degrees Celsius.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }17 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right or left side of a volume of semiconductor material may be to the conceptual limit of a particular unit cell and not to an actual physical end of the material.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A junction field-effect transistor device having an integrated temperature sensor, the junction field-effect transistor device comprising:
a junction field-effect transistor;
a temperature sensor material having a first charge carrier polarity and being implanted into an area of semiconductor material having a second charge carrier polarity, wherein the area is adjacent to the junction field-effect transistor,
the temperature sensor material containing a plurality of dopants and exhibiting an electrical resistance that increases with a number of ionized ones of the dopants, with the number of ionized dopants increasing with a temperature of the temperature sensor material; and
first and second electrical terminals provided spaced-apart on the temperature sensor material to measure the electrical resistance of the temperature sensor material,
wherein the electrical resistance measured between the first and second electrical terminals may be translated into a temperature value for the integrated temperature sensor and the junction field-effect transistor.

2. The junction field-effect transistor device of claim 1, wherein a thickness of the temperature sensor material is between one-tenth (0.1) micrometer and one-half (0.5) micrometer.

3. The junction field-effect transistor device of claim 1, wherein the junction field-effect transistor includes a gate, and one of the first and second electrical terminals is connected to the gate.

4. The junction field-effect transistor device of claim 1, wherein the integrated temperature sensor is capable of measuring a range of temperatures between a room temperature and a temperature at which all the dopants are ionized.

5. The junction field-effect transistor device of claim 4, wherein the temperature at which all the dopants are ionized is less than or equal to two-thousand degrees Celsius.

6. The junction field-effect transistor device of claim 1, wherein a number of the dopants determines the electrical resistance of the temperature sensor material, and more dopants results in lower electrical resistance.

7. The junction field-effect transistor device of claim 1, wherein the dopants are selected from the group consisting of: boron, aluminum, gallium, and indium.

8. The junction field-effect transistor device of claim 1, wherein the temperature sensor material is P-type and the semiconductor material is N-type.

9. A junction field-effect transistor device having an integrated temperature sensor, the junction field-effect transistor device comprising:
a junction field-effect transistor having a gate;
a temperature sensor material having a first charge carrier polarity and being implanted into an area of semiconductor material having a second charge carrier polarity, wherein the area is adjacent to the gate of the junction field-effect transistor,
the temperature sensor material having a thickness between one-tenth (0.1) micrometer and one-half (0.5) micrometer,
the temperature sensor material containing a plurality of dopants and exhibiting an electrical resistance that increases with a number of ionized ones of the dopants, with the number of ionized dopants increasing with a temperature of the temperature sensor material; and
first and second electrical terminals provided spaced-apart on the temperature sensor material to measure the electrical resistance of the temperature sensor material,
wherein the electrical resistance measured between the first and second terminals may be translated into a temperature value for the integrated temperature sensor and the junction field-effect transistor, and wherein the integrated temperature sensor is capable of measuring a range of electrical resistance corresponding to a range of temperatures between a room temperature and a temperature at which all the dopants are ionized.

10. The junction field-effect transistor device of claim 9, wherein one of the first and second temperature sensor terminals is connected to the gate of the junction field-effect transistor.

11. The junction field-effect transistor device of claim 9, wherein the temperature at which all the dopants are ionized is two thousand (2000) degrees Celsius.

12. The junction field-effect transistor device of claim 9, wherein the dopants are selected from the group consisting of: boron, aluminum, gallium, and indium.

13. The junction field-effect transistor device of claim 9, wherein the temperature sensor material is P-type and the semiconductor material is N-type.

14. A method of making a junction field-effect transistor device having an integrated temperature sensor, the method comprising:
providing an area of semiconductor material having a first charge carrier polarity adjacent to a gate of a junction field-effect transistor;
providing a temperature sensor material having a second charge carrier polarity in the area of semiconductor material, wherein the temperature sensor material contains a plurality of dopants and exhibits an electrical resistance that increases with a number of ionized ones of the dopants, and the number of ionized dopants increases with a temperature of the temperature sensor material; and
providing first and second electrical terminals spaced-apart on the temperature sensor material to measure the electrical resistance of the temperature sensor material;
wherein the electrical resistance measured between the first and second terminals may be translated into a temperature value for the integrated temperature sensor and the junction field-effect transistor, and the integrated temperature sensor is capable of measuring a range of temperatures between a room temperature and a temperature at which all the dopants are ionized.

15. The method of claim 14, wherein a thickness of the temperature sensor material is between one-tenth (0.1) micrometer and one-half (0.5) micrometer.

16. The method of claim 14, wherein one of the first and second temperature sensor terminals is connected to the gate of the junction field-effect transistor.

17. The method of claim 14, wherein the temperature at which all the dopants are ionized is two thousand (2000) degrees Celsius.

18. The method of claim 14, wherein the dopants are selected from the group consisting of: boron, aluminum, gallium, and indium.

19. The method of claim 14, wherein the temperature sensor material is P-type and the semiconductor material is N-type.
